(19) United States
(12) Patent Application Publication
(10) Pub. No.: US 2026/0223575 A1
(43) Pub. Date: Jul. 30, 2026

(54) LIGHT EMITTING DISPLAY DEVICE

(71) Applicant: LG Display Co., Ltd., Seoul (KR)

(72) Inventors: Seung Hyun KIM, Paju-si (KR); Yu Jeong LEE, Paju-si (KR); Eun Jung PARK, Paju-si (KR); Chun Ki KIM, Paju-si (KR)

(73) Assignee: LG Display Co., Ltd., Seoul (KR)

(21) Appl. No.: 19/415,285

(22) Filed: Dec. 10, 2025

(30) Foreign Application Priority Data
Jan. 24, 2025 (KR) 10-2025-0011979

(51) Int. Cl. H10K 59/80; H10K 59/00; H10K 59/32

(52) U.S. Cl. CPC H10K 59/876; H10K 59/32; H10K 59/771; H10K 59/80518

(57) ABSTRACT

Disclosed is a light emitting display device including a substrate on which a plurality of sub-pixels is disposed and a light emitting device disposed in each of the plurality of sub-pixels. The light emitting device includes a transparent electrode and a reflective electrode facing each other. Between the transparent electrode and the reflective electrode, a first light emitting stack including a first light emitting layer, a second light emitting stack including a second light emitting layer, a third light emitting stack including a third light emitting layer, and a fourth light emitting stack including a fourth light emitting layer are sequentially disposed, with charge generation layers interposed therebetween. At least one of the first to fourth light emitting layers is shifted by a predetermined vertical distance toward the transparent electrode from a maximum cavity peak position relative to the reflective electrode.

This application claims the benefit of Korean Patent Application No. 10-2025-0011979, filed on Jan. 24, 2025, which is hereby incorporated by reference as if fully set forth herein.

### BACKGROUND

### Technical Field

The present disclosure relates to a light emitting display device that reduces noticeable color deviation caused by changes in viewing angle and improves visual perception by minimizing or at least reducing characteristic variations caused by changes in viewing angle.

### Discussion of the Related Art

Recently, a self-emissive display device has been considered a competitive application because it does not require a separate light source and enables implementation of a compact device design and vivid color display. The self-emissive display device may be classified into an organic light emitting display device and an inorganic light emitting display device depending on the light emitting material therein.

Such a self-emissive display device includes a plurality of sub-pixels and a light emitting device provided in each of the sub-pixels, thereby emitting light without a separate light source.

As a display device achieves high resolution and high integration, a tandem device that forms a common organic layer and light emitting layer without requiring a fine metal mask has gained attention from the perspective of processability, and various studies thereon have been conducted.

### SUMMARY

Accordingly, embodiments of the present disclosure are directed to a light emitting display device that substantially obviates one or more problems due to limitations and disadvantages of the related art.

To improve the luminance efficiency of a light emitting display device, a structure of increasing the number of light emitting stacks has been proposed.

When the number of light emitting stacks increases, luminance deviation for each color may occur according to changes in viewing angle, and thus various issues such as color wash out, brightness loss, and color shift may be observed. An aspect of embodiments of the present disclosure is to address such issues caused by changes in viewing angle.

An aspect of the present disclosure is to provide a light emitting display device that minimizes or at least reduces variations in color coordinates and luminance according to changes in viewing angle in a four-stack structure, thereby improving visual perception under changes in viewing angle.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a light emitting display device may comprise a substrate on which a plurality of sub-pixels is disposed and a light emitting device in each of the plurality of sub-pixels, the light emitting device comprising a transparent electrode and a reflective electrode facing each other, and a first light emitting stack comprising a first light emitting layer, a first charge generation layer on the first light emitting stack, a second light emitting stack comprising a second light emitting layer on the first charge generation layer, a second charge generation layer on the second light emitting stack, a third light emitting stack comprising a third light emitting layer on the second charge generation layer, a third charge generation layer on the third light emitting stack, and a fourth light emitting stack comprising a fourth light emitting layer on the third charge generation layer, between the transparent electrode and the reflective electrode. At least one of the first to fourth light emitting layers may be shifted by a predetermined vertical distance toward the transparent electrode from a maximum cavity peak position relative to the reflective electrode.

In another aspect, a light emitting display device may comprise a substrate on which a plurality of sub-pixels is disposed and a light emitting device in each of the plurality of sub-pixels, the light emitting device comprising a transparent electrode and a reflective electrode facing each other, and an intermediate layer disposed between the transparent electrode and the reflective electrode, wherein the intermediate layer includes a first common layer, a first light emitting layer, a second common layer, a second light emitting layer, a third common layer, a third light emitting layer, a fourth common layer, a fourth light emitting layer, and a fifth common layer, which are sequentially disposed in a direction from the transparent electrode toward the reflective electrode, and wherein a thickness of at least one of the first to fifth common layers is disposed so that, at least one of the first to fourth light emitting layers is shifted by a predetermined vertical distance toward the transparent electrode from a maximum cavity peak position relative to the reflective electrode.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles of the disclosure. In the drawings:

FIG. 1 illustrates a cross-sectional view of a light emitting device according to an embodiment of the present disclosure and a contour map corresponding thereto;

FIG. 2 is a cross-sectional view of the light emitting device according to the embodiment of the present disclosure;

FIG. 3 is a cross-sectional view showing a light emitting display device according to an embodiment of the present disclosure;

FIG. 4 is a cross-sectional view showing a first light emitting device of a first experimental example and a second light emitting device of a second experimental example;

FIG. 5 is a graph showing luminance efficiency for each color and color deviation depending on the viewing angle in the first experimental example;

FIG. 6 is a graph showing luminance efficiency for each color and color deviation depending on the viewing angle in the second experimental example;

FIGS. 7A to 7D are cross-sectional views showing a third light emitting device of a third experimental example, a fourth light emitting device of a fourth experimental example, a fifth light emitting device of a fifth experimental example, and a sixth light emitting device of a sixth experimental example;

FIGS. 8A and 8B are graphs showing color wash out characteristics of red, green, and blue wavelengths in a first light emitting device and a sixth light emitting device;

FIGS. 9A and 9B are graphs showing color shift phenomena of red, green, and blue wavelengths in the first light emitting device and the sixth light emitting device;

FIGS. 10A and 10B are graphs showing brightness loss characteristics in the first light emitting device and the sixth light emitting device;

FIG. 11 is a graph showing the light emitting intensity according to wavelength at various viewing angles in the first light emitting device;

FIG. 12 is a graph showing the light emitting intensity according to wavelength at various viewing angles in the sixth light emitting device;

FIG. 13 is a view showing comparison between maximum cavity peak positions of light emitting layers in the first light emitting device and shifted positions of light emitting layers in the light emitting device of the present disclosure; and

FIGS. 14 to 17 illustrate cross-sectional views of light emitting devices according to other embodiments of the present disclosure and contour maps corresponding thereto.

### DETAILED DESCRIPTION

Reference will now be made in detail to embodiments of the disclosure, examples of which are illustrated in the accompanying drawings. Wherever possible, the same reference numbers will be used throughout the drawings to refer to the same or like parts. In the following description of the disclosure, detailed descriptions of known functions and configurations incorporated herein will be omitted when the same may obscure the subject matter of the disclosure. In addition, the names of elements used in the following description are selected in consideration of clarity of description of the disclosure, and may differ from the names of elements of actual products.

The shapes, sizes, ratios, angles, numbers, and the like, which are illustrated in the drawings to describe various example embodiments of the present disclosure are merely given by way of example. The disclosure is not limited to the illustrations in the drawings.

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

As used herein, the term “doped” layer refers to a layer including a first material and a second material (for example, n-type and p-type materials, or organic and inorganic substances) having physical properties different from the first material. Apart from the differences in properties, the first and second materials can also differ in terms of their amounts in the doped layer. For example, the host material can be a major component while the dopant material can be a minor component. The first material accounts for most of the weight of the doped layer. The second material can be added in an amount less than 30 wt %, based on a total weight of the first material in the doped layer. A “doped” layer can be a layer in which a host material may be distinguished from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt %, or when the p-type material is present in an amount of less than 30 wt, the layer is considered to be a “doped” layer.

Further, the term “undoped” layer refers to layers that are not “doped”. For example, a layer can be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

In this present disclosure, an electroluminescence (EL) spectrum can be calculated by multiplying (a) a photoluminescence (PL) spectrum, which reflects the inherent characteristics of an emissive material such as a dopant material or a host material included in an organic emission layer, by (b) an outcoupling emittance spectrum curve, which is determined by the structure and optical characteristics of an organic light-emitting element including the thicknesses of organic layers such as, for example, a hole transport layer and an electron transport layer.

Hereinafter, exemplary embodiments of the present disclosure will be described with reference to the accompanying drawings.

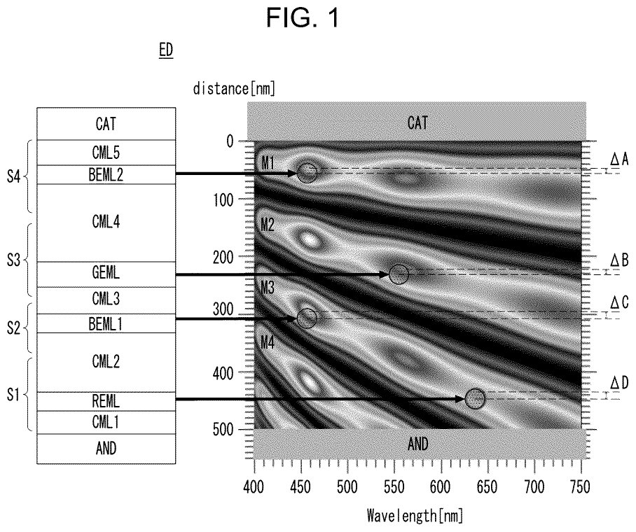

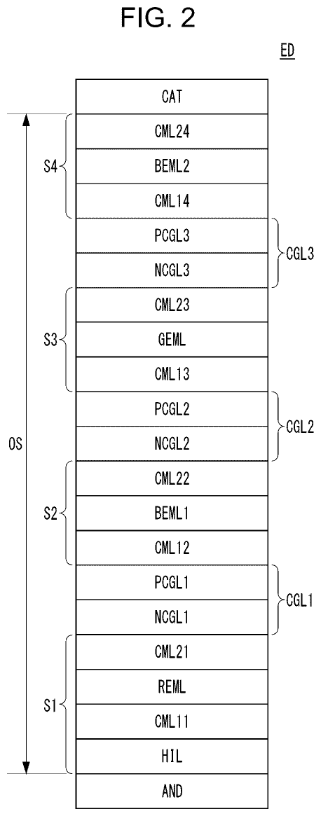

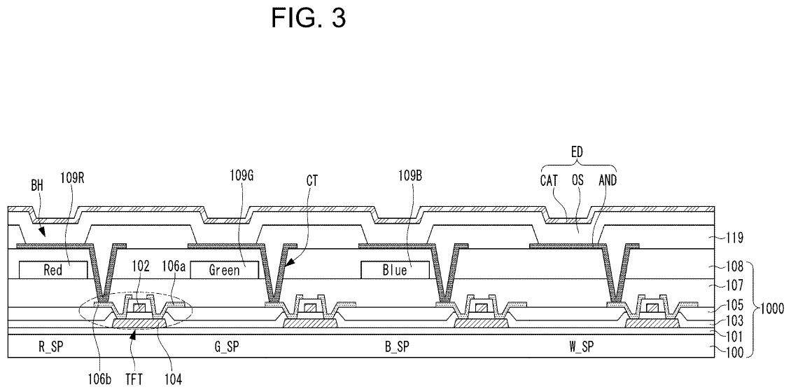

FIG. 1 illustrates a cross-sectional view of a light emitting device according to an embodiment of the present disclosure and a contour map corresponding thereto. FIG. 2 is a cross-sectional view of the light emitting device according to the embodiment of the present disclosure. FIG. 3 is a cross-sectional view showing a light emitting display device according to an embodiment of the present disclosure.

As shown in FIGS. 1 to 3, the light emitting display device according to the embodiment of the present disclosure includes a substrate 100, on which a plurality of sub-pixels R_SP, G_SP, B_SP, and W_SP is disposed, and a light emitting device ED, which is disposed in each of the plurality of sub-pixels R_SP, G_SP, B_SP, and W_SP and includes a transparent electrode AND, a reflective electrode CAT disposed opposite the transparent electrode AND, and an intermediate layer OS disposed between the transparent electrode AND and the reflective electrode CAT.

Contour maps of the present disclosure represent positions of optimal light emission in the intermediate layer OS between the transparent electrode AND and the reflective electrode CAT. And, in the contour maps, M1, M2, M3, M4, and M5 mean contour lines sequentially generated from the reflective electrode CAT. Each contour line has a certain slope in a relationship between wavelength and a distance from the reflective electrode CAT.

The intermediate layer OS of the light emitting device ED includes a first light emitting stack S1 including a first light emitting layer REML, a first charge generation layer CGL1 disposed on the first light emitting stack S1, a second light emitting stack S2 disposed on the first charge generation layer CGL1 and including a second light emitting layer BEML1, a second charge generation layer CGL2 disposed on the second light emitting stack S2, a third light emitting stack S3 disposed on the second charge generation layer CGL2 and including a third light emitting layer GEML, a third charge generation layer CGL3 disposed on the third light emitting stack S3, and a fourth light emitting stack S4 disposed on the third charge generation layer CGL3 and including a fourth light emitting layer BEML2.

In the light emitting device ED according to the embodiment shown in FIGS. 1 and 2, the light emitting layers disposed from the transparent electrode AND to the reflective electrode CAT are disposed in an order of a red light emitting layer REML, a first blue light emitting layer BEML1, a green light emitting layer GEML, and a second blue light emitting layer BEML2. That is, the light emitting device ED has red/blue/green/blue arrangement from the transparent electrode AND to the reflective electrode CAT. This is merely one example, and the arrangement order of the light emitting layers may vary. The arrangement of the light emitting layers according to another embodiment will be described later.

The transparent electrode AND includes, for example, indium tin oxide (ITO) or indium zinc oxide (IZO), and functions as an anode of the light emitting device ED.

The reflective electrode CAT functions as a cathode of the light emitting device ED. For example, the reflective electrode CAT may include a single-layer structure formed of one selected from among aluminum (Al), silver (Ag), molybdenum (Mo), gold (Au), magnesium (Mg), calcium (Ca), and barium (Ba), or an alloy of two or more thereof.

The light emitting device ED resonates between the transparent electrode AND and the reflective electrode CAT under different resonance conditions according to the wavelengths of the respective light emitting layers included in the intermediate layer OS, and light is ultimately emitted through the transparent electrode AND and the substrate 100.

The light emitting device ED includes different light emitting layers REML, BEML1, GEML, and BEML2 that emit light of different colors, which are combined to emit white light. As shown in FIG. 3, a red filter 109R, a green filter 109G, and a blue filter 109B may be provided between the substrate 100 and the light emitting device ED in the respective sub-pixels R_SP, G_SP, and B_SP, so that light of a predetermined wavelength from white light may be selectively transmitted through the respective sub-pixels R_SP, G_SP, and B_SP.

That is, red light may be transmitted through the red filter 109R in the red sub-pixel R_SP, green light may be transmitted through the green filter 109G in the green sub-pixel G_SP, and blue light may be transmitted through the blue filter 109B in the blue sub-pixel B_SP.

The red sub-pixel R_SP, the white sub-pixel W_SP, the blue sub-pixel B_SP, and the green sub-pixel G_SP described in the present disclosure refer to a plurality of divided regions disposed within an active area AA on the substrate 100. FIG. 3 shows a unit pixel including the red, white, blue, and green sub-pixels R_SP, W_SP, B_SP, and G_SP.

The substrate 100 may include at least one of a glass base, a plastic film, or a metal plate having a predetermined supporting strength. The substrate 100 may be formed of a flexible material. For example, when the substrate 100 has a multilayer structure, the substrate 100 may have a stacked structure including a first organic film, an inorganic insulating layer, and a second organic film. The first organic film disposed at the outermost position may function to prevent the introduction of external impurities and to provide protection. The second organic film may enable planarization of the surface on which the internal array structure is formed and may prevent the transfer of charges or impurities from the outside to the inside. The inorganic insulating layer between the first and second organic films may function to prevent permeation or diffusion of moisture between the first and second organic films and the transfer of conductive impurities to the second organic film.

The red sub-pixel R_SP, the white sub-pixel W_SP, the blue sub-pixel B_SP, and the green sub-pixel G_SP include a red light emitting portion, a white light emitting portion, a blue light emitting portion, and a green light emitting portion, respectively, and further include non-light: emitting portions provided around the respective light emitting portions.

The non-light emitting portions may be regions in which banks 119 defining the light emitting portions of the sub-pixels are disposed. The banks 119 disposed in the non-light emitting portions between adjacent light emitting portions are connected to each other.

In the light emitting display device according to the embodiment of the present disclosure, a light emitting device ED is provided in each of the red sub-pixel R_SP, the white sub-pixel W_SP, the blue sub-pixel B_SP, and the green sub-pixel G_SP. The light emitting device ED includes a transparent electrode AND, an intermediate layer OS, and a reflective electrode CAT. The intermediate layer OS includes a plurality of light emitting stacks and charge generation layers disposed between the light emitting stacks. The light emitting device ED in each of the red sub-pixel R_SP, the white sub-pixel W_SP, the blue sub-pixel B_SP, and the green sub-pixel G_SP has a structure including a common intermediate layer OS and reflective electrode CAT. That is, in the red sub-pixel R_SP, the white sub-pixel W_SP, the blue sub-pixel B_SP, and the green sub-pixel G_SP, the intermediate layer OS includes a plurality of light emitting stacks and charge generation layers and is disposed in the same stacked structure.

When the intermediate layer OS having a common stacked structure is provided in each sub-pixel, yield may be improved compared to a structure in which a plurality of deposition masks is used to separately pattern each sub-pixel.

Furthermore, luminance may be improved by stacking a plurality of light emitting stacks.

The bank 119 is disposed in the non-light emitting portion and exposes the light emitting portion of each transparent electrode AND through an opening BH. The bank 119 is disposed to cover an edge of each transparent electrode AND. The bank 119 may be open through the opening BH, and the transparent electrode AND may be exposed through the region in which the bank 119 is open.

The bank 119 may be formed of a transparent or opaque organic material. When the bank 119 includes an opaque organic material, the bank 119 may include a light-shielding organic material that absorbs or blocks at least a portion of wavelengths in the visible spectrum. The light-shielding organic material refers to a material that absorbs light, and includes an organic material that absorbs at least a portion of wavelengths in the visible spectrum. The bank 119 may include a material such as black carbon or a color pigment. The bank 119 may be formed in a stacked structure including a light-shielding organic material layer and a light-transmitting organic material layer or may be formed in a single-layer structure including a light-transmitting organic material layer.

A circuit including a plurality of transistors TFT and at least one storage capacitor may be provided in each of the sub-pixels R_SP, W_SP, B_SP, and G_SP on the substrate 100, and may be selectively driven. Although FIG. 3 illustrates, as an example, that one transistor TFT is provided in each of the sub-pixels SP (R_SP, W_SP, B_SP, and G_SP), each sub-pixel may include two or more transistors as needed. The pixel circuit in each of the sub-pixels R_SP, W_SP, B_SP, and G_SP may include at least one switching transistor configured to control turn-on of each of the sub-pixels R_SP, W_SP, B_SP, and G_SP and a driving transistor configured to supply a driving current to the light emitting device ED.

The transparent electrode AND may be separately provided in each of the plurality of sub-pixels R_SP, G_SP, B_SP, and W_SP, and the reflective electrode CAT may be continuously provided across the plurality of sub-pixels. The transparent electrode AND may be connected to the transistor TFT disposed between the substrate 100 and the light emitting device ED.

As an example, the transistor TFT may include a gate electrode 102, an active layer 104, and source and drain electrodes 106a and 106b connected to both sides of the active layer 104. A channel protection layer may further be provided on a region of the active layer 104 in which a channel is positioned in order to prevent direct contact between the source/drain electrodes 106a and 106b and the active layer 104. A buffer layer 101 may be provided on the substrate 100, and the transistor TFT may be disposed on the buffer layer 101.

A light-shielding pattern may further be provided below the transistor TFT with the buffer layer 101 interposed therebetween. The light-shielding pattern may prevent light from entering the active layer 104 from the underside of the substrate 100, thereby stabilizing the off-state characteristics of the transistor.

A gate insulating layer 103 is provided between the gate electrode 102 and the active layer 104.

The active layer 104 may be formed of, for example, any one of an oxide semiconductor, amorphous silicon, and polycrystalline silicon or a combination of two or more of these materials. For example, when the active layer 104 is formed of an oxide semiconductor, the heat treatment temperature required for forming the transistor may be reduced, thereby increasing the freedom in selecting the substrate 100, which may be advantageous for application to a flexible display device.

A gate electrode 102 may be provided on the gate insulating layer 103, and an interlayer insulating layer 105 may further be provided between the gate electrode 102 and the source/drain electrodes 106a and 106b.

In addition, the drain electrode 106b of the transistor TFT may be connected to the transparent electrode AND through a contact hole CT formed in the first and second passivation layers 107 and 108.

The first passivation layer 107 is provided to primarily protect the transistor TFT. As an example, the color filters 109R, 109G, and 109B may be provided on the first passivation layer 107.

The second passivation layer 108 may be provided on the first passivation layer 107 including the color filters 109R, 109G, and 109B.

As shown in FIG. 3, when the plurality of sub-pixels includes the red sub-pixel R_SP, the white sub-pixel W_SP, the blue sub-pixel B_SP, and the green sub-pixel G_SP, the color filters are provided such that the red filter 109R, the green filter 109G, and the blue filter 109B are disposed in the respective sub-pixels R_SP, G_SP, and B_SP other than the white sub-pixel W_SP.

White light emitted through the transparent electrode AND may be selectively transmitted for each wavelength component.

The transparent electrode AND is formed on the surface of the second passivation layer 108, excluding the contact hole CT, and is connected to one of the drain electrode 106b and the source electrode 106a of the transistor TFT, thereby receiving an electrical signal through the transistor TFT.

In this case, the structure including the substrate 100, the thin film transistor TFT, the color filters 109R, 109G, and 109B, and the first and second passivation layers 107 and 108 may be referred to as a thin film transistor array substrate 1000.

The second passivation layer 108 may include an organic insulating material.

For example, the organic insulating material may include at least one of acrylic resin, phenolic resin, polyimide resin, unsaturated polyester resin, polyamide resin, benzocyclobutene, polyphenylene resin, or polyphenylene sulfide resin.

The light emitting device ED is formed on the thin film transistor array substrate 1000, on which the bank 119 that defines the light emitting portion of each of the sub-pixels R_SP, W_SP, B_SP, and G_SP within the opening BH is disposed.

In the light emitting display device, the transparent electrodes AND respectively provided in the red, white, blue, and green sub-pixels R_SP, W_SP, B_SP, and G_SP are spaced apart from each other and are independently driven.

The intermediate layer OS may include a plurality of light emitting stacks and may have the same structure across the plurality of sub-pixels R_SP, W_SP, B_SP, and G_SP.

In the light emitting device ED of the light emitting display device according to the present disclosure, at least the intermediate layer OS is commonly provided across the sub-pixels R_SP, G_SP, B_SP, and W_SP.

As shown in FIG. 3, the light emitting device ED may include a plurality of light emitting stacks S1, S2, S3, and S4 and charge generation layers CGL1, CGL2, and CGL3 disposed between the light emitting stacks, which are disposed between the transparent electrode AND and the reflective electrode CAT. The light emitting device ED, having a common structure across the sub-pixels R_SP, G_SP, B_SP, and W_SP, may emit white light.

Red light, blue light, and green light may be emitted through the red filter 109R, the blue filter 109B, and the green filter 109G respectively provided in the red sub-pixel R_SP, the blue sub-pixel B_SP, and the green sub-pixel G_SP.

The white sub-pixel W_SP may not include a color filter, and white light from the light emitting device ED may be directly emitted through the substrate 100.

As an example, as shown in FIG. 2, in the intermediate layer OS, the first light emitting stack S1 that emits red light, the second light emitting stack S2 that emits blue light, the third light emitting stack S3 that emits green light, and the fourth light emitting stack S4 that emits blue light may be stacked in that order.

The light emitting stacks S1, S2, S3, and S4 may respectively include light emitting layers REML, BEML1, GEML, and BEML2, common layers CML11, CML12, CML13, and CML14 having hole-transporting properties and provided under the light emitting layers REML, BEML1, GEML, and BEML2, and common layers CML21, CML22, CML23, and CML24 electron-transporting properties and provided on the light emitting layers REML, BEML1, GEML, and BEML2. The common layers CML11, CML12, CML13, and CML14 may include a hole injection layer, a hole transport layer, and an electron blocking layer. The common layers CML21, CML22, CML23, and CML24 may include a hole blocking layer, an electron transport layer, and an electron injection layer.

Because the color filters 109R, 109B, and 109W are provided between the light emitting devices ED and the substrate 100, it is possible to individually realize colors other than white in the respective sub-pixels R_SP, B_SP, and G_SP. In the white sub-pixel W_SP, which does not include a color filter, white light is emitted through the light emitting device ED.

According to the light emitting display device of the present disclosure, since the light emitting device including four light emitting stacks is commonly provided in the plurality of sub-pixels R_SP, G_SP, B_SP, and W_SP, it is possible to compensate for color and luminance characteristics according to changes in viewing angle, thereby ultimately reducing noticeable color deviation caused by changes in viewing angle.

To this end, as shown in FIG. 1, at least one of the light emitting layers REML, BEML1, GEML, and BEML2 included in the first to fourth light emitting stacks S1 to S4 is vertically shifted from a maximum cavity peak position in a direction from the reflective electrode CAT toward the transparent electrode AND.

In this case, the vertical distances AA, AB, AC, and AD, by which the red light emitting layer REML, the first blue light emitting layer BEML1, the green light emitting layer GEML, and the second blue light emitting layer BEML2 are shifted from the maximum cavity peak position in a direction from the reflective electrode CAT toward the transparent electrode AND, may range from 30 Å to 140 Å.

Generally, in a light emitting device including a plurality of stacks, each light emitting layer is disposed at a maximum cavity peak position relative to the reflective electrode CAT in order to achieve optimal efficiency.

In the light emitting display device of the present disclosure, at least one of the light emitting layers is shifted by a predetermined distance from the maximum cavity peak position in order to minimize or at least reduce variation in characteristics caused by changes in viewing angle.

Referring to FIG. 1, the first common layer CML1 is disposed between the transparent electrode AND and the red light emitting layer REML, the second common layer CML2 is disposed between the red light emitting layer REML and the first blue light emitting layer BEML1, the third common layer CML3 is disposed between the first blue light emitting layer BEML1 and the green light emitting layer GEML, the fourth common layer CML4 is disposed between the green light emitting layer GEML and the second blue light emitting layer BEML2, and the fifth common layer CML5 is disposed between the second blue light emitting layer BEML2 and the reflective electrode CAT.

Referring to FIG. 2, the first common layer CML1 may be included in the first light emitting stack S1 and may include a hole injection layer HIL and a first hole transport layer CML11.

The second common layer CML2 may include a first electron transport layer CML21 of the first light emitting stack S1, which is disposed on the red light emitting layer REML, a first charge generation layer CGL1, and a second hole transport layer CML12 of the second light emitting stack S2.

The third common layer CML3 may include a second electron transport layer CML22, which is a part of the second light emitting stack S2, a second charge generation layer CGL2, and a third hole transport layer CML13, which is a part of the third light emitting stack S3.

The fourth common layer CML4 may include a third electron transport layer CML23, which is a part of the third light emitting stack S3, a third charge generation layer CGL3, and a fourth hole transport layer CML14, which is a part of the fourth light emitting stack S4.

The fifth common layer CML5 may be included in the fourth light emitting stack S4 and may include a fourth electron transport layer CML24 and an electron injection layer.

In the light emitting stacks S1, S2, S3, and S4, the common layers CML11, CML12, CML13, and CML14 disposed under the light emitting layers REML, BEML1, GEML, and BEML2 may include a hole injection layer, a hole transport layer, and an electron blocking layer, and the common layers CML21, CML22, CML23, and CML24 disposed on the light emitting layers REML, BEML1, GEML, and BEML2 may include a hole blocking layer, an electron transport layer, and an electron injection layer.

In the light emitting device according to the embodiment of the present disclosure, the vertical distances by which the red light emitting layer REML, the first blue light emitting layer BEML1, the green light emitting layer GEML, and the second blue light emitting layer BEML2 are shifted toward the transparent electrode AND may be located within the common layers CML1, CML2, CML3, CML4, and CML5.

In the four-stack structure, because the light emitting layers are disposed in the respective light emitting stacks, front brightness is improved. However, because the light emitting layers are independently disposed in the respective light emitting stacks, brightness varies greatly when observed from different viewing angles.

Table 1 below shows viewing angle characteristics of a three-stack structure and a four-stack structure.

For example, the three-stack structure includes three light emitting stacks between a transparent electrode and a reflective electrode. In this structure, first and second blue light emitting layers are included in first and third light emitting stacks, respectively, and a red light emitting layer and a green light emitting layer are disposed in contact with each other in a second light emitting stack.

In contrast, as shown in FIG. 2, the four-stack structure includes four light emitting stacks between the transparent electrode AND and the reflective electrode CAT. The red light emitting layer REML, the first blue light emitting layer BEML1, the green light emitting layer GEML, and the second blue light emitting layer BEML2 are disposed between the transparent electrode AND and the reflective electrode CAT. Each light emitting layer is disposed between the common layers in a corresponding light emitting stack, and thus is spaced apart from the light emitting layers of the other light emitting stacks.

In the four-stack structure shown in Table 1, each of the light emitting layers is disposed at a maximum cavity peak position relative to the reflective electrode CAT. This structure differs from the embodiment of the present disclosure in which at least one light emitting layer is shifted from the maximum cavity peak position.

Table 1 shows viewing angles at which color wash out of 20.0% or more based on the color characteristics in the front view is observed, viewing angles at which color shift of 16.0% or more based on the color characteristics in the front view is observed, and viewing angles at which brightness loss of 24.0% or more based on the front brightness is observed in the three-stack structure and the four-stack structure.

TABLE 1

| | | | Brightness |
|---|---|---|---|
| | Color Wash Out | Color Shift | Loss |
| Classification | 20.0% | 16.0% | 24.0% |
| 3-stack | 60° | 46° | 69° |
| Structure | | | |
| 4-stack | 53° | 40° | 56° |
| Structure | | | |

Referring to Table 1, it can be seen that the four-stack structure exhibits color wash out, color shift, and brightness loss at smaller viewing angles than the three-stack structure. That is, a four-stack light emitting device that is simply optimized for front brightness tends to exhibit increased brightness variation with changes in viewing angle, intensified color coordinate variation, and color distortion across different viewing angles. The four-stack structure shown in Table 1 is believed to exhibit these issues because the intermediate layer is designed to match the cavity characteristics in the front view, resulting in greater efficiency loss across various viewing angles and thus aggravating color variation. In addition, because the light emitting regions for red, green, and blue are distributed differently, differences in efficiency loss occur depending on the angle. This leads to color coordinate variation and color distortion.

The light emitting display device according to the embodiment of the present disclosure addresses the issues of increased brightness variation with changes in viewing angle, intensified color coordinate variation, and color distortion across different viewing angles. The features of the embodiment of the present disclosure will be described in comparison with a first light emitting device ED1 of a first experimental example, in which light emitting layers are disposed at positions corresponding to maximum cavity peak characteristics between a transparent electrode and a reflective electrode.

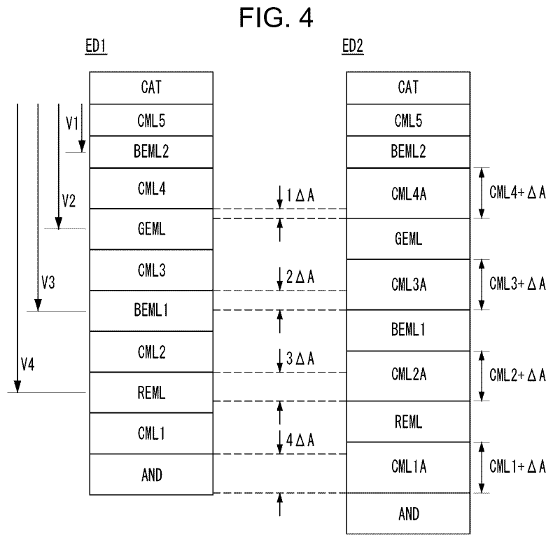

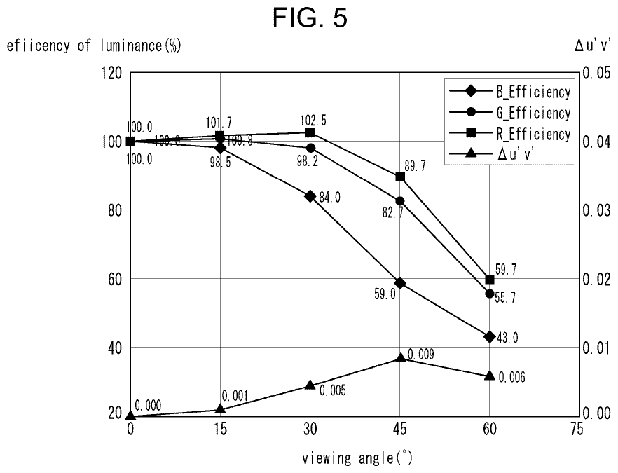

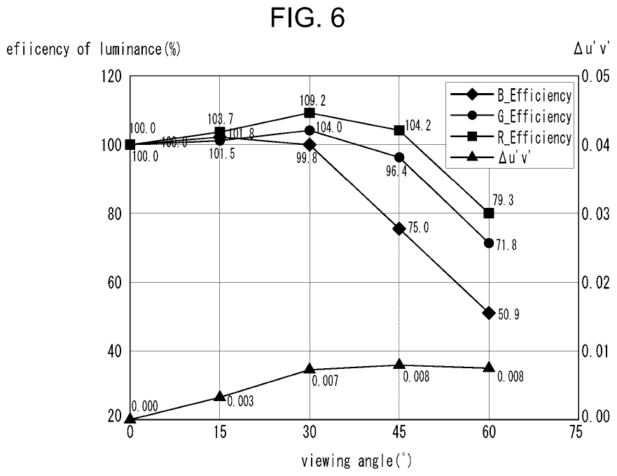

FIG. 4 is a cross-sectional view showing a first light emitting device of a first experimental example and a second light emitting device of a second experimental example. FIG. 5 is a graph showing luminance efficiency for each color and color deviation depending on the viewing angle in the first experimental example. FIG. 6 is a graph showing luminance efficiency for each color and color deviation depending on the viewing angle in the second experimental example.

As shown in FIG. 4, the first light emitting device ED1 of the first experimental example includes a first common layer CML1, a red light emitting layer REML, a second common layer CML2, a first blue light emitting layer BEML1, a third common layer CML3, a green light emitting layer GEML, a fourth common layer CML4, a second blue light emitting layer BEML2, and a fifth common layer CML5, which are disposed between a transparent electrode AND and a reflective electrode CAT. In this case, the red light emitting layer REML, the first blue light emitting layer BEML1, the green light emitting layer GEML, and the second blue light emitting layer BEML2 are disposed at positions corresponding to the maximum cavity peaks in the front view.

The center of the second blue light emitting layer BEML2 has a maximum cavity peak at a first vertical distance V1 from the reflective electrode CAT. The center of the green light emitting layer GEML has a maximum cavity peak at a second vertical distance V2 from the reflective electrode CAT. The center of the first blue light emitting layer BEML1 has a maximum cavity peak at a third vertical distance V3 from the reflective electrode CAT. The center of the red light emitting layer REML has a maximum cavity peak at a fourth vertical distance V4 from the reflective electrode CAT.

In the second light emitting device ED2 of the second experimental example corresponding to an embodiment of the present disclosure, each of a first common layer CML1A, a second common layer CML2A, a third common layer CML3A, and a fourth common layer CML4A is increased in thickness by a first interval ΔA compared to a corresponding one of the first to fourth common layers CML1, CML2, CML3, and CML4 of the first light emitting device ED1. The center of the green light emitting layer GEML may be spaced toward the transparent electrode AND by a first interval ΔA from the second vertical distance V2 at which the maximum cavity peak is obtained. The center of the first blue light emitting layer BEML1 may be spaced toward the transparent electrode AND by twice the first interval (2ΔA) from the third vertical distance V3 at which the maximum cavity peak is obtained. The center of the red light emitting layer REML may be spaced toward the transparent electrode AND by three times the first interval (3ΔA) from the fourth vertical distance V4 at which the maximum cavity peak is obtained.

Referring to FIG. 5, in the first light emitting device ED1, in which each light emitting layer is positioned to have a maximum cavity peak relative to the reflective electrode, it is observed that the luminance efficiency of blue greatly varies, and the luminance efficiencies of red and green greatly degrade at viewing angles of 45° or more. In contrast, referring to FIG. 6, in the second light emitting device ED2, in which each light emitting layer is vertically shifted toward the transparent electrode from the position corresponding to the maximum cavity peak, the luminance efficiencies of red, green, and blue at viewing angles of 45° or less are all maintained at 75% or more compared to the front brightness, indicating that color wash out, color shift, and brightness loss are barely noticeable at viewing angles of 45° or less. Furthermore, the color deviation characteristics remain substantially uniform as the viewing angle changes from 30° to 60°, resulting in minimal perceptual difference for the viewer, thereby reducing visual recognition of image quality degradation caused by changes in viewing angle.

In the second light emitting device ED2 shown in FIG. 4, which corresponds to an embodiment of the present disclosure, the thicknesses of all of the first to fourth common layers CML1, CML2, CML3, and CML4 are increased compared to those of the first light emitting device ED1. However, the viewing angle characteristics may also be improved even when the thicknesses of the common layers are increased based on any one of the common layers.

In this case, the first interval ΔA may be 30 Å or more.

Hereinafter, experiments conducted to verify the above-described effects will be described.

In the experiments to be described below, the thicknesses of common layers between light emitting layers were selectively increased by the first interval ΔA. In the experiments, the first interval was set to 35 Å. However, the embodiments of the present disclosure are not limited thereto. In the embodiments of the present disclosure, the minimum value of the first interval may be set to 30 Å in consideration of process variation.

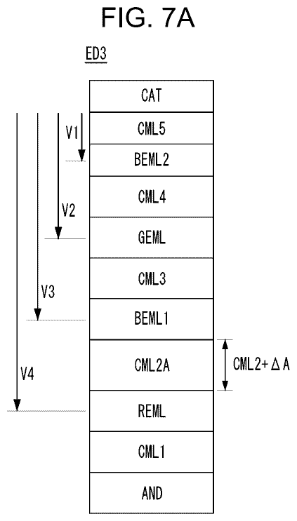

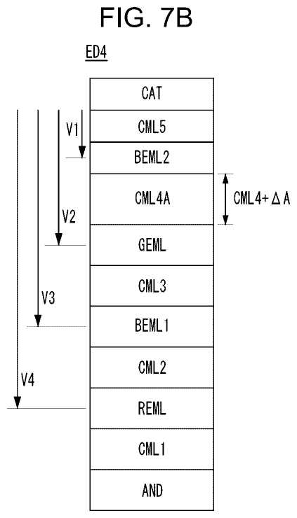

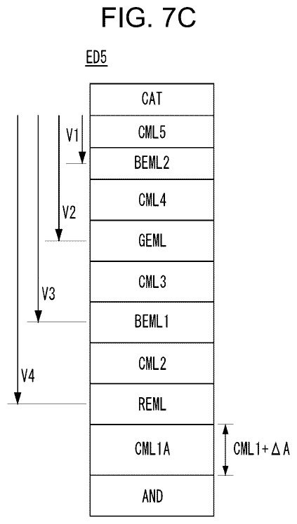

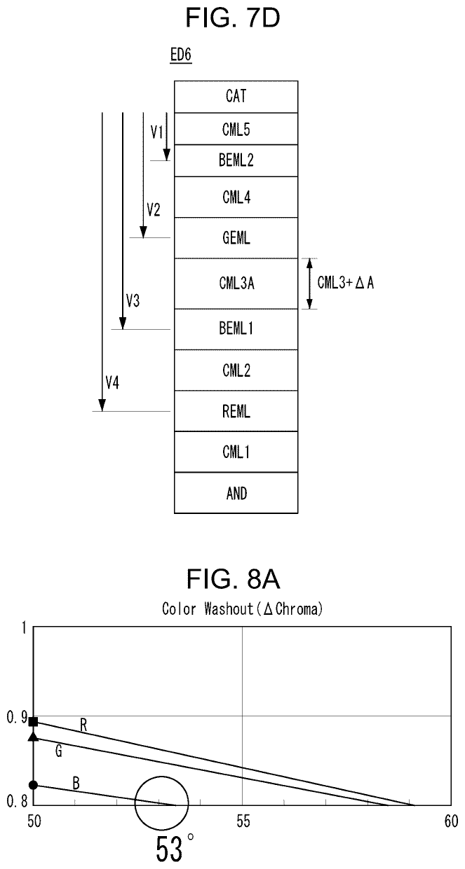

FIGS. 7A to 7D are cross-sectional views showing a third light emitting device of a third experimental example, a fourth light emitting device of a fourth experimental example, a fifth light emitting device of a fifth experimental example, and a sixth light emitting device of a sixth experimental example.

As shown in FIG. 7A, the third light emitting device ED3 of the third experimental example is configured such that the thickness of the second common layer CML2A is increased by the first interval ΔA so as to shift the position of the red light emitting layer REML from the position corresponding to the maximum cavity peak.

As shown in FIG. 7B, the fourth light emitting device ED4 of the fourth experimental example is configured such that the thickness of the fourth common layer CML4A is increased by the first interval ΔA so as to shift the positions of the light emitting layers disposed below the second blue light emitting layer BEML2 from the positions corresponding to the maximum cavity peaks.

As shown in FIG. 7C, the fifth light emitting device ED5 of the fifth experimental example is configured such that the thickness of the first common layer CML1A is increased by the first interval ΔA so as to change the vertical position of the transparent electrode AND from the reflective electrode CAT.

As shown in FIG. 7D, the sixth light emitting device ED6 of the sixth experimental example is configured such that the thickness of the third common layer CML3A disposed at the center of the intermediate layers is increased by the first interval ΔA. In this case, the green light emitting layer GEML and the second blue light emitting layer BEML2 disposed above the third common layer CML3A are located at positions corresponding to the maximum cavity peaks, and the red light emitting layer REML and the first blue light emitting layer BEML1 disposed below the third common layer CML3A are shifted toward the transparent electrode AND by the first interval ΔA from the positions corresponding to the maximum cavity peaks.

TABLE 2

| | | | Brightness |
|---|---|---|---|
| | Color Wash Out | Color Shift | Loss |
| Classification | 20.0% | 16.0% | 24.0% |
| ED1 | 54° | 41° | 59° |
| ED3 | 60° | 42° | 64° |
| ED4 | 60° | 42° | 64° |
| ED5 | 62° | 44° | 64° |
| ED6 | 66° | 44° | 65° |

Referring to Table 2, compared to the first light emitting device ED1 of the first experimental example, all of the third light emitting device ED3 of the third experimental example, the fourth light emitting device ED4 of the fourth experimental example, the fifth light emitting device ED5 of the fifth experimental example, and the sixth light emitting device ED6 of the sixth experimental example exhibit improved viewing angle characteristics in terms of color wash out, color shift, and brightness loss.

It can also be seen that, among the third to sixth experimental examples, the case in which the thickness of the common layer disposed at the center of the light emitting device is changed exhibits the most excellent viewing angle characteristics.

Hereinafter, the viewing angle characteristics for each color will be described through comparison between the first light emitting device ED1 of the first experimental example and the sixth light emitting device ED6 of the sixth experimental example.

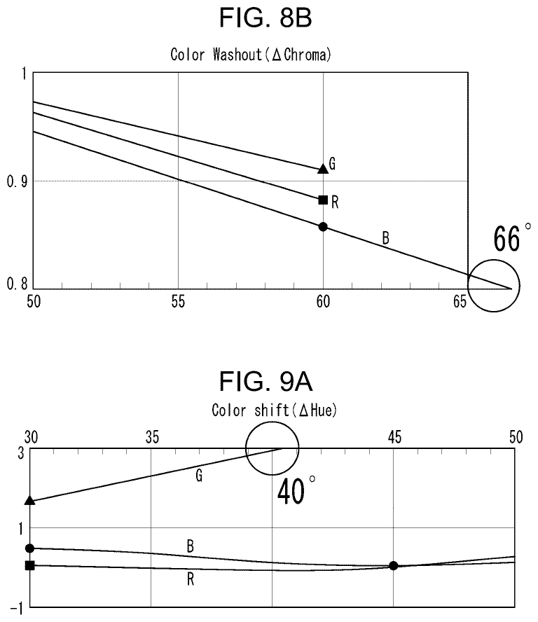

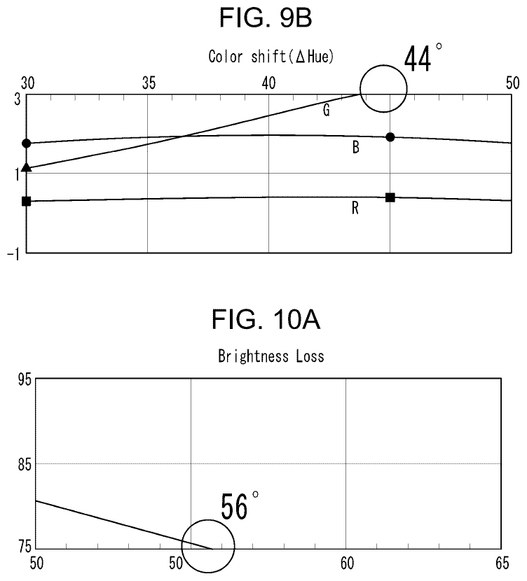

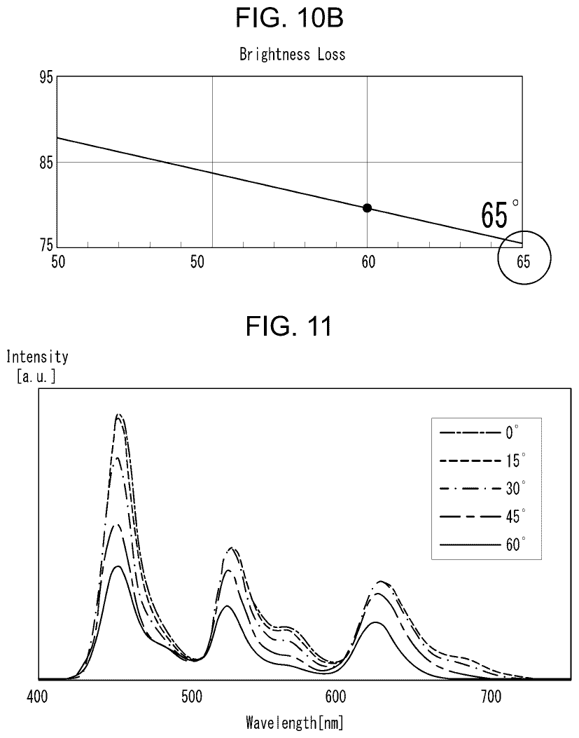

FIGS. 8A and 8B are graphs showing color wash out characteristics of red, green, and blue wavelengths in the first light emitting device and the sixth light emitting device. FIGS. 9A and 9B are graphs showing color shift phenomena of red, green, and blue wavelengths in the first light emitting device and the sixth light emitting device. FIGS. 10A and 10B are graphs showing brightness loss characteristics in the first light emitting device and the sixth light emitting device.

Referring to FIGS. 8A and 8B, in the first light emitting device, it can be seen that the color wash out of blue exceeds a visual threshold of 20.0% at a viewing angle of 54°. In contrast, in the sixth light emitting device in which at least one of the light emitting layers provided in the light emitting device is shifted toward the transparent electrode from the position corresponding to the maximum cavity peak, it can be seen that the color wash out characteristics are improved in the order of green, red, and blue, and the color wash out characteristics of blue, which are poorest, are visually perceived at a viewing angle of 66°, indicating that the sixth light emitting device exhibits excellent viewing angle characteristics in terms of color wash out.

Referring to FIGS. 9A and 9B, in the first light emitting device, it can be seen that the color shift phenomenon of green exceeds a visual threshold of 16.0% at a viewing angle of 40°. In contrast, in the sixth light emitting device in which at least one of the light emitting layers provided in the light emitting device is shifted toward the transparent electrode from the position corresponding to the maximum cavity peak, it can be seen that the color shift is visually perceived at a viewing angle of 44°, indicating that the sixth light emitting device exhibits excellent color shift characteristics compared to the first light emitting device.

Referring to FIGS. 10A and 10B, it can also be seen that, in the first light emitting device, brightness loss of 24.0% or more with respect to the front brightness is visually perceived at a viewing angle of 56° and that, in the sixth light emitting device, brightness loss of 24.0% or more with respect to the front brightness is visually perceived at a viewing angle of 65°.

That is, compared to the first light emitting device, the sixth light emitting device maintains characteristics within the visual threshold at wider viewing angles in terms of color wash out, color shift, and brightness loss. Therefore, it can be seen that the sixth light emitting device provides more stable characteristics under changes in viewing angle and reduces the perceptibility of color deviation caused by changes in the viewer's angle of view.

Table 3 below shows the front brightness, color coordinate, and color viewing angle characteristics and the color gamut of the first light emitting device ED1 and the sixth light emitting device ED6.

It can be seen that the first light emitting device ED1 and the sixth light emitting device ED6 exhibit similar front luminance efficiencies and similar overlap ratios that represent the color gamut.

The sixth light emitting device ED6 exhibits improved green purity efficiency in terms of color coordinate characteristics compared to the first light emitting device ED1. In addition, the sixth light emitting device ED6 has a relatively low Δu′ v′ (Max) value, which represents color viewing angle characteristics, thereby exhibiting improved color viewing angle characteristics compared to the first light emitting device ED1.

TABLE 3

| | | |
|---|---|---|
| Classification | ED1 | ED6 |

| | | | |
|---|---|---|---|
| Efficiency (Cd/A) | R | 17.05 | 16.5 |
| (@ full white) | G | 56.47 | 55.7 |
| | B | 7.33 | 7.6 |
| | W | 124.65 | 125.1 |
| Color Coordinates | Rx | 0.693 | 0.693 |
| | Ry | 0.306 | 0.305 |
| | Gx | 0.216 | 0.220 |
| | Gy | 0.723 | 0.718 |
| | Bx | 0.150 | 0.148 |
| | By | 0.045 | 0.0407 |
| | Wx | 0.283 | 0.283 |
| | Wy | 0.296 | 0.299 |

| | | |
|---|---|---|
| Δu′v′ (Max) | 0.015 | 0.011 |
| Color Gamut (DCI) | 99.3 | 99.3 |
| (Overlap Ratio) (%) | | |

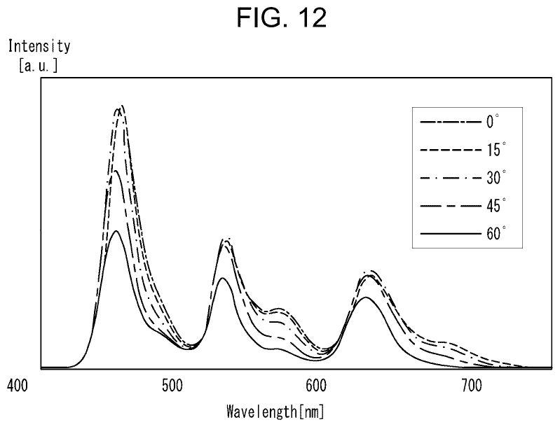

FIG. 11 is a graph showing the light emitting intensity according to wavelength at various viewing angles in the first light emitting device. FIG. 12 is a graph showing the light emitting intensity according to wavelength at various viewing angles in the sixth light emitting device.

Referring to FIGS. 11 and 12, it can be seen that, when the light emitting intensity according to wavelength is observed at viewing angles of 15°, 30°, 45°, and 60° vary from the front viewing angle of 0°, the sixth light emitting device exhibits higher light emitting intensity than the first light emitting device at all viewing angles. This indicates that the sixth light emitting device secures a certain level or higher of luminance efficiency under changes in viewing angle, thereby preventing significant luminance degradation due to changes in viewing angle and thus preventing or reducing visual recognition of image quality degradation caused by changes in viewing angle.

Hereinafter, the arrangement of the light emitting layers disposed at the maximum cavity peak positions in the four-stack light emitting device and the distances by which the light emitting layers are shifted from the maximum cavity peak positions will be described.

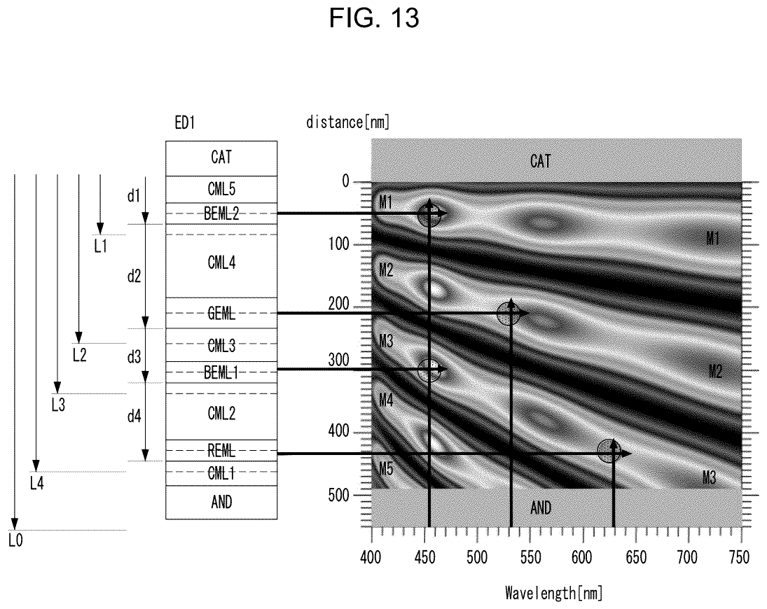

FIG. 13 is a view showing comparison between the maximum cavity peak positions of the light emitting layers in the first light emitting device and the shifted positions of the light emitting layers in the light emitting device of the present disclosure.

The first light emitting device ED1 shown in FIG. 13 is configured such that the light emitting layers are disposed at the maximum cavity peak positions. In the first light emitting device ED1, a distance from the lower surface of the reflective electrode CAT to the lower surface of the second blue light emitting layer BEML2 is represented by d1, a distance from the lower surface of the second blue light emitting layer BEML2 to the lower surface of the green light emitting layer GEML is represented by d2, a distance from the lower surface of the green light emitting layer GEML to the lower surface of the first blue light emitting layer BEML1 is represented by d3, and a distance from the lower surface of the first blue light emitting layer BEML1 to the lower surface of the red light emitting layer REML is represented by d4.

In the light emitting device according to the embodiment of the present disclosure, a first distance L1 from the lower surface of the reflective electrode CAT to the lower surface of the second blue light emitting layer BEML2 may be greater than d1, a second distance L2 from the lower surface of the reflective electrode CAT to the lower surface of the green light emitting layer GEML may be greater than d1+d2, a third distance L3 from the lower surface of the reflective electrode CAT to the lower surface of the first blue light emitting layer BEML1 may be greater than d1+d2+d3, and a fourth distance L4 from the lower surface of the reflective electrode CAT to the lower surface of the red light emitting layer REML may be greater than d1+d2+d3+d4.

In the first light emitting device ED1, the first to fourth light emitting stacks include common layers disposed on and under the first to fourth light emitting layers.

The light emitting device shown in FIG. 13 includes four light emitting stacks, and each contour line representing light emitting characteristics with respect to wavelength may include four modes within the visible spectrum.

According to respective modes of the four contour lines, the maximum cavity peak positions relative to the reflective electrode CAT may be defined as follows.

The distance d1 from the reflective electrode to the lower surface of the second blue light emitting layer, which is the closest to the reflective electrode and has the maximum cavity peak, is defined as 0.115λb (λb representing blue wavelength). The distance from the reflective electrode to the lower surface of the green light emitting layer, which is the second closest to the reflective electrode and has the maximum cavity peak, is defined as 0.115λg+λg/2n (n representing refractive index and λg representing green wavelength). The distance from the reflective electrode to the lower surface of the first blue light emitting layer, which is the third closest to the reflective electrode and has the maximum cavity peak, is defined as 0.115λb+λb/n. The distance from the reflective electrode to the lower surface of the red light emitting layer, which is the farthest from the reflective electrode and has the maximum cavity peak, is defined as 0.115λr+λr/n (λr representing red wavelength).

The maximum cavity peak position of the second blue light emitting layer BEML2, which is the closest to the reflective electrode, may be located at a first vertical distance (d1=0.115λb) from the reflective electrode, the first vertical distance being 0.115 times the wavelength of the light emitted from the second blue light emitting layer BEML2.

The maximum cavity peak position of the green light emitting layer GEML may be located at a second vertical distance (d1+d2) from the reflective electrode, the second vertical distance being a sum of the first vertical distance (d1=0.115λb) and a value (d2=λg/2n) obtained by dividing the wavelength of the light emitted from the green light emitting layer by 2n (n being the refractive index of the intermediate layer between the transparent electrode and the reflective electrode).

The maximum cavity peak position of the first blue light emitting layer BEML1 may be located at a third vertical distance (d1+d2+d3) from the reflective electrode, the third vertical distance being a sum of the second vertical distance and a value (d3=λb/2n) obtained by dividing the wavelength of the light emitted from the first blue light emitting layer by 2n (n being the refractive index of the intermediate layer between the transparent electrode and the reflective electrode).

The maximum cavity peak position of the red light emitting layer REML may be located at a fourth vertical distance (d1+d2+d3+d4) from the reflective electrode, the fourth vertical distance being a sum of the third vertical distance and a value (d4=λr/2n) obtained by dividing the wavelength of the light emitted from the red light emitting layer by 2n (n being the refractive index of the intermediate layer between the transparent electrode and the reflective electrode).

In this case, d1 may be 53 nm or more, d2 may be 164 nm or more, d3 may be 79 nm, and d4 may be 154 nm. The distance from the lower surface of the red light emitting layer REML to the upper surface of the transparent electrode AND corresponds to 32 nm.

d2 may be at least three times d1, and d4 may be at least two times d3.

Referring to FIG. 13, in the light emitting device according to the embodiment of the present disclosure, the second blue light emitting layer may be shifted from the maximum cavity peak position thereof toward the transparent electrode such that the vertical distance L1 from the cathode to lower surface of the second blue light emitting layer BEML2 may be greater than 53 nm.

For example, the second blue light emitting layer may be shifted downward by at least 30 Å from the maximum cavity peak position thereof by increasing the thickness of the overlying common layer.

Alternatively, the position L2 of the lower surface of the green light emitting layer from the reflective electrode may be shifted downward by at least 30 Å from the maximum cavity peak position of the green light emitting layer.

Alternatively, the position L3 of the lower surface of the first blue light emitting layer from the reflective electrode may be shifted downward by at least 30 Å from the maximum cavity peak position of the first blue light emitting layer.

Alternatively, the position L4 of the lower surface of the red light emitting layer from the reflective electrode may be shifted downward by at least 30 Å from the maximum cavity peak position of the red light emitting layer.

In the light emitting device according to the embodiment of the present disclosure, because the thickness of a part of the common layers is increased so that the light emitting layers are shifted away from the reflective electrode, the distance L0 from the reflective electrode to the lower surface of the transparent electrode may also be increased by “4ΔA” compared to the structure (light emitting device of the first experimental example) in which each of the light emitting layers is located at the maximum cavity peak position. In this case, ΔA may be 30 Å or more.

In this case, the red light emitting layer REML has a thickness of 200 Å, the green light emitting layer GEML has a thickness of 350 Å, and the first and second blue light emitting layers BEML1 and BEML2 have a thickness of 250 Å.

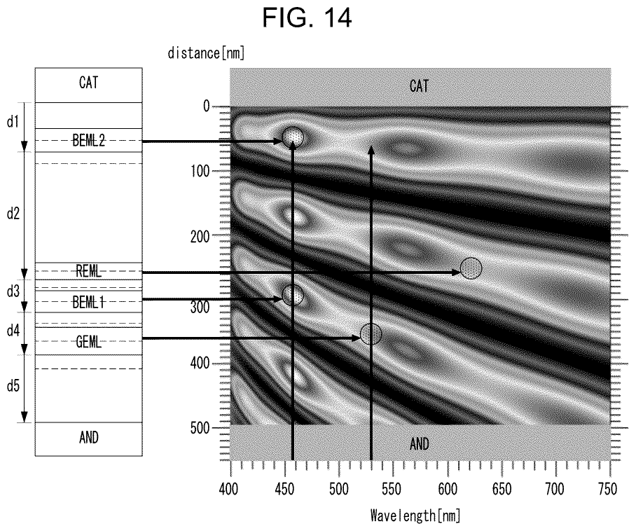

FIGS. 14 to 17 illustrate cross-sectional views of light emitting devices according to other embodiments of the present disclosure and contour maps corresponding thereto.

Referring to FIG. 14, a green light emitting layer GEML, a first blue light emitting layer BEML1, a red light emitting layer REML, and a second blue light emitting layer BEML2 may be disposed from below to above in that order between a transparent electrode AND and a reflective electrode CAT.

In this case, a vertical distance d1 from the reflective electrode CAT to the lower surface of the second blue light emitting layer BEML2 is 53 nm or more, and a vertical distance d2 from the lower surface of the second blue light emitting layer BEML2 to the lower surface of the red light emitting layer REML is 203 nm or more. A vertical distance d3 from the lower surface of the red light emitting layer REML to the lower surface of the first blue light emitting layer BEML1 is 40 nm or more, and a vertical distance d4 from the lower surface of the first blue light emitting layer BEML1 to the lower surface of the green light emitting layer GEML is 72 nm or more. A vertical distance d5 from the lower surface of the green light emitting layer GEML to the upper surface of the transparent electrode AND is 114 nm or more. That is, a thickness of the intermediate layer OS disposed between the transparent electrode AND and the reflective electrode CAT is 482 nm or more (i.e., a sum of d1 to d5).

The vertical distance d2 from the lower surface of the second blue light emitting layer BEML2 to the lower surface of the red light emitting layer REML may be at least 3.8 times the vertical distance d1 from the reflective electrode CAT to the lower surface of the second blue light emitting layer BEML2 (d2≥3.8d1). The vertical distance d4 from the lower surface of the first blue light emitting layer BEML1 to the lower surface of the green light emitting layer GEML may be at least 1.8 times the vertical distance d3 from the lower surface of the red light emitting layer REML to the lower surface of the first blue light emitting layer BEML1 (d4≥1.8d3).

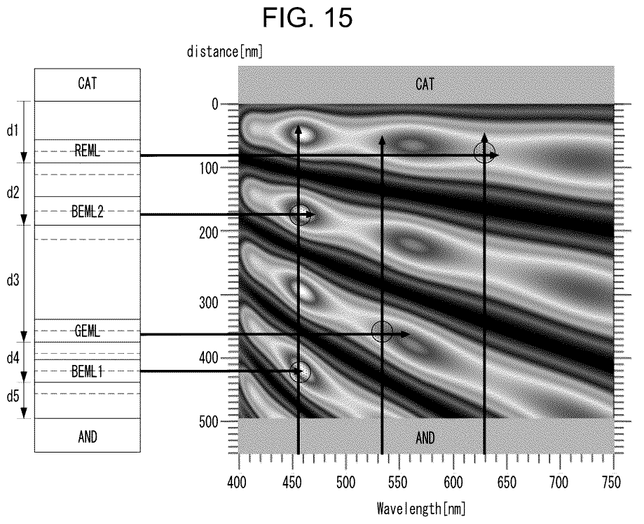

Referring to FIG. 15, a first blue light emitting layer BEML1, a green light emitting layer GEML, a second blue light emitting layer BEML2, and a red light emitting layer REML may be disposed from below to above in that order between a transparent electrode AND and a reflective electrode CAT.

In this case, a vertical distance d1 from the reflective electrode CAT to the lower surface of the red light emitting layer REML is 78 nm or more, and a vertical distance d2 from the lower surface of the red light emitting layer REML to the lower surface of the second blue light emitting layer BEML2 is 98 nm or more. A vertical distance d3 from the lower surface of the second blue light emitting layer BEML2 to the lower surface of the green light emitting layer GEML is 189 nm or more, and a vertical distance d4 from the lower surface of the green light emitting layer GEML to the lower surface of the first blue light emitting layer BEML1 is 62 nm or more. A vertical distance d5 from the lower surface of the first blue light emitting layer BEML1 to the upper surface of the transparent electrode AND is 55 nm or more. That is, a thickness of the intermediate layer OS disposed between the transparent electrode AND and the reflective electrode CAT is 482 nm or more (i.e., a sum of d1 to d5).

The vertical distance d2 from the lower surface of the red light emitting layer REML to the lower surface of the second blue light emitting layer BEML2 may be at least 1.25 times the vertical distance d1 from the reflective electrode AND to the lower surface of the red light emitting layer REML (d2≥1.25d1). The vertical distance d4 from the lower surface of the green light emitting layer GEML to the lower surface of the first blue light emitting layer BEML1 may be at least 0.3 times the vertical distance d3 from the lower surface of the second blue light emitting layer BEML2 to the lower surface of the green light emitting layer GEML (d4≥0.3d3).

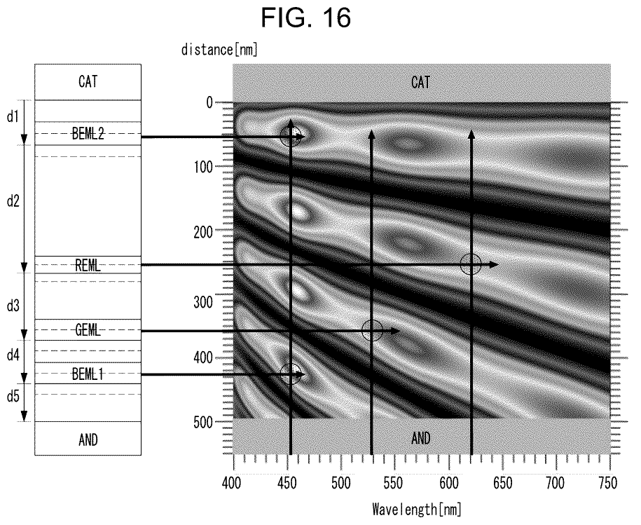

Referring to FIG. 16, a first blue light emitting layer BEML1, a green light emitting layer GEML, a red light emitting layer REML, and a second blue light emitting layer BEML2 may be disposed from below to above in that order between a transparent electrode AND and a reflective electrode CAT.

In this case, a vertical distance d1 from the reflective electrode CAT to the lower surface of the second blue light emitting layer BEML2 is 53 nm or more, and a vertical distance d2 from the lower surface of the second blue light emitting layer BEML2 to the lower surface of the red light emitting layer REML is 203 nm or more. A vertical distance d3 from the lower surface of the red light emitting layer REML to the lower surface of the green light emitting layer GEML is 109 nm or more, and a vertical distance d4 from the lower surface of the green light emitting layer GEML to the lower surface of the first blue light emitting layer BEML1 is 62 nm or more. A vertical distance d5 from the lower surface of the first blue light emitting layer BEML1 to the upper surface of the transparent electrode AND is 55 nm or more. That is, a thickness of the intermediate layer OS disposed between the transparent electrode AND and the reflective electrode CAT is 482 nm or more (i.e., a sum of d1 to d5).

The vertical distance d2 from the lower surface of the second blue light emitting layer BEML2 to the lower surface of the red light emitting layer REML may be at least 3.8 times the vertical distance d1 from the reflective electrode CAT to the lower surface of the second blue light emitting layer BEML2 (d2≥3.8d1). The vertical distance d4 from the lower surface of the green light emitting layer GEML to the lower surface of the first blue light emitting layer BEML1 may be at least 0.55 times the vertical distance d3 from the lower surface of the red light emitting layer REML to the lower surface of the green light emitting layer GEML (d4≥0.55d3).

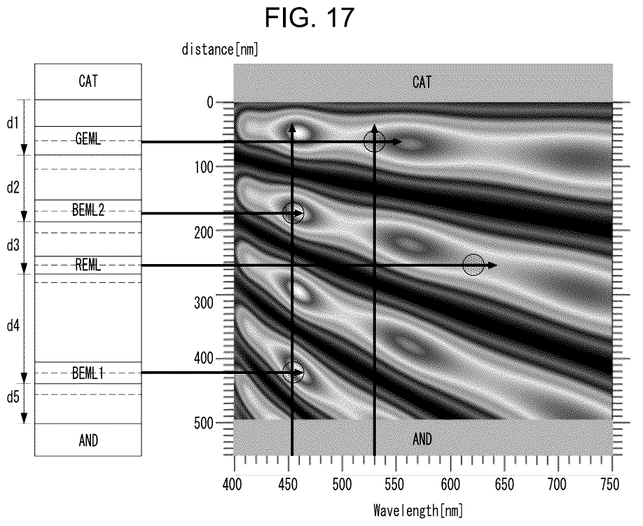

Referring to FIG. 17, a first blue light emitting layer BEML1, a red light emitting layer REML, a second blue light emitting layer BEML2, and a green light emitting layer GEML may be disposed from below to above in that order between a transparent electrode AND and a reflective electrode CAT.

In this case, a vertical distance d1 from the reflective electrode to the lower surface of the green light emitting layer GEML is 69 nm or more, and a vertical distance d2 from the lower surface of the green light emitting layer GEML to the lower surface of the second blue light emitting layer BEML2 is 107 nm or more. A vertical distance d3 from the lower surface of the second blue light emitting layer BEML2 to the lower surface of the red light emitting layer REML is 83 nm or more, and a vertical distance d4 from the lower surface of the red light emitting layer REML to the lower surface of the first blue light emitting layer BEML1 is 168 nm or more. A vertical distance d5 from the lower surface of the first blue light emitting layer to the upper surface of the transparent electrode AND is 55 nm or more. That is, a thickness of the intermediate layer OS disposed between the transparent electrode AND and the reflective electrode CAT is 482 nm or more (i.e., a sum of d1 to d5).

The vertical distance d2 from the lower surface of the green light emitting layer GEML to the lower surface of the second blue light emitting layer BEML2 may be at least 1.5 times the vertical distance d1 from the reflective electrode CAT to the lower surface of the green light emitting layer GEML (d2≥1.5d1). The vertical distance d4 from the lower surface of the red light emitting layer REML to the lower surface of the first blue light emitting layer BEML1 may be at least two times the vertical distance d3 from the lower surface of the second blue light emitting layer BEML2 to the lower surface of the red light emitting layer REML (d4≥2d3).

Among the red light emitting layer, the green light emitting layer, and the first and second blue light emitting layers, the green light emitting layer may be the thickest, and the red light emitting layer may be the thinnest.

The transparent electrode may be separately provided in each of the plurality of sub-pixels, and the reflective electrode may be continuously provided across the plurality of sub-pixels. The transparent electrode may be connected to a transistor disposed between the substrate and the light emitting device.

The light emitting display device according to the embodiment of the present disclosure may include a four-stack structure, thereby improving luminance efficiency.

In the light emitting device, at least one of the light emitting layers independently provided in respective light emitting stacks is disposed at a position shifted from a vertical position corresponding to a maximum cavity peak, thereby reducing viewing angle sensitivity and enabling gradual changes in color characteristics according to changes in viewing angle. Accordingly, it is possible to reduce phenomena such as color wash out, color shift, and brightness loss at high viewing angles and to prevent visual perception degradation caused by changes in viewing angle.

The positions of the light emitting layers are adjusted by modifying a common layer such as a hole transport layer or an electron transport layer, rather than modifying the light emitting layers themselves. That is, the thickness of a common layer adjacent to the light emitting layer between the transparent electrode and the reflective electrode is increased to increase the total thickness of the organic layers, thereby adjusting the vertical positions of the light emitting layers to positions at which color coordinate and luminance variations caused by changes in viewing angle are minimized or at least reduced.

The light emitting device according to the embodiment of the present disclosure may minimize or at least reduce variations in characteristics and visual recognition of image quality degradation caused by changes in viewing angle, thereby improving visual perception

As is apparent from the above description, the light emitting display device according to the embodiment of the present disclosure may include a four-stack structure, thereby improving luminance efficiency.

The light emitting device according to the embodiment of the present disclosure may vary the thickness of an organic layer between the transparent electrode and the reflective electrode within a limited range, thereby improving the viewing angle characteristics of a multi-light-emitting-stack structure having high efficiency without increasing driving voltage. This may satisfy various demands of viewers and contribute to sustainability, thereby enabling the implementation of Environmental/Social/Governance (ESG).

A light emitting display device according to one embodiment of the present disclosure may comprise a substrate on which a plurality of sub-pixels is disposed and a light emitting device in each of the plurality of sub-pixels, the light emitting device comprising a transparent electrode and a reflective electrode facing each other, and a first light emitting stack comprising a first light emitting layer, a first charge generation layer on the first light emitting stack, a second light emitting stack comprising a second light emitting layer on the first charge generation layer, a second charge generation layer on the second light emitting stack, a third light emitting stack comprising a third light emitting layer on the second charge generation layer, a third charge generation layer on the third light emitting stack, and a fourth light emitting stack comprising a fourth light emitting layer on the third charge generation layer, between the transparent electrode and the reflective electrode. At least one of the first to fourth light emitting layers may be shifted by a predetermined vertical distance toward the transparent electrode from a maximum cavity peak position relative to the reflective electrode.

In a light emitting display device according to one embodiment of the present disclosure, the vertical distance may be equal to or greater than 30 Å and equal to or less than 140 Å.

In a light emitting display device according to one embodiment of the present disclosure, the first to fourth light emitting stacks may comprise common layers disposed on and under the first to fourth light emitting layers, and the vertical distance may be located within the common layers.

In a light emitting display device according to one embodiment of the present disclosure, the maximum cavity peak position of the fourth light emitting layer, closest to the reflective electrode, may be located at a first vertical distance from the reflective electrode, the first vertical distance being 0.115 times a wavelength of light emitted from the fourth light emitting layer.

The maximum cavity peak position of the third light emitting layer may be located at a second vertical distance from the reflective electrode, the second vertical distance being a sum of the first vertical distance and a value obtained by dividing a wavelength of light emitted from the third light emitting layer by 2n, n being a refractive index of an intermediate layer between the transparent electrode and the reflective electrode.

The maximum cavity peak position of the second light emitting layer may be located at a third vertical distance from the reflective electrode, the third vertical distance being a sum of the second vertical distance and a value obtained by dividing a wavelength of light emitted from the second light emitting layer by 2n.

The maximum cavity peak position of the first light emitting layer may be located at a fourth vertical distance from the reflective electrode, the fourth vertical distance being a sum of the third vertical distance and a value obtained by dividing a wavelength of light emitted from the first light emitting layer by 2n.

In a light emitting display device according to one embodiment of the present disclosure, the fourth light emitting layer may be spaced apart from the reflective electrode by a vertical distance greater than the first vertical distance by at least 30 Å.

The third light emitting layer may be spaced apart from the reflective electrode by a vertical distance greater than the second vertical distance by at least 30 Å.

The second light emitting layer may be spaced apart from the reflective electrode by a vertical distance greater than the third vertical distance by at least 30 Å.

The first light emitting layer is spaced apart from the reflective electrode by a vertical distance greater than the fourth vertical distance by at least 30 Å.

In a light emitting display device according to one embodiment of the present disclosure, the first to fourth light emitting layers may comprise a red light emitting layer, a green light emitting layer, and first and second blue light emitting layers.

In a light emitting display device according to one embodiment of the present disclosure, the first to fourth light emitting layers may be disposed between the transparent electrode and the reflective electrode in an order of the red light emitting layer, the first blue light emitting layer, the green light emitting layer, and the second blue light emitting layer.

In a light emitting display device according to one embodiment of the present disclosure, a vertical distance between a lower surface of the second blue light emitting layer and a lower surface of the green light emitting layer may be at least three times a vertical distance between the reflective electrode and the lower surface of the second blue light emitting layer.

In a light emitting display device according to one embodiment of the present disclosure, a vertical distance between a lower surface of the first blue light emitting layer and a lower surface of the red light emitting layer may be at least two times a vertical distance between a lower surface of the green light emitting layer and the lower surface of the first blue light emitting layer.

In a light emitting display device according to one embodiment of the present disclosure, the first to fourth light emitting layers may be disposed between the transparent electrode and the reflective electrode in an order of the green light emitting layer, the first blue light emitting layer, the red light emitting layer, and the second blue light emitting layer.

In a light emitting display device according to one embodiment of the present disclosure, a vertical distance between a lower surface of the second blue light emitting layer and a lower surface of the red light emitting layer may be at least 3.8 times a vertical distance between the reflective electrode and the lower surface of the second blue light emitting layer. A vertical distance between a lower surface of the first blue light emitting layer and a lower surface of the green light emitting layer may be at least 1.8 times a vertical distance between the lower surface of the red light emitting layer and the lower surface of the first blue light emitting layer.

In a light emitting display device according to one embodiment of the present disclosure, the first to fourth light emitting layers may be disposed between the transparent electrode and the reflective electrode in an order of the first blue light emitting layer, the green light emitting layer, the second blue light emitting layer, and the red light emitting layer.

In a light emitting display device according to one embodiment of the present disclosure, a vertical distance between a lower surface of the red light emitting layer and a lower surface of the second blue light emitting layer may be at least 1.25 times a vertical distance between the reflective electrode and the lower surface of the red light emitting layer.

A vertical distance between a lower surface of the green light emitting layer and a lower surface of the first blue light emitting layer may be at least 0.3 times a vertical distance between the lower surface of the second blue light emitting layer and the lower surface of the green light emitting layer.

In a light emitting display device according to one embodiment of the present disclosure, the first to fourth light emitting layers may be disposed between the transparent electrode and the reflective electrode in an order of the first blue light emitting layer, the green light emitting layer, the red light emitting layer, and the second blue light emitting layer.

In a light emitting display device according to one embodiment of the present disclosure, a vertical distance between a lower surface of the second blue light emitting layer and a lower surface of the red light emitting layer may be at least 3.8 times a vertical distance between the reflective electrode and a lower surface of the second blue light emitting layer. A vertical distance between a lower surface of the green light emitting layer and the lower surface of the first blue light emitting layer may be at least 0.55 times a vertical distance between the lower surface of the red light emitting layer and the lower surface of the green light emitting layer.

In a light emitting display device according to one embodiment of the present disclosure, the first to fourth light emitting layers may be disposed between the transparent electrode and the reflective electrode in an order of the first blue light emitting layer, the red light emitting layer, the second blue light emitting layer, and the green light emitting layer.

In a light emitting display device according to one embodiment of the present disclosure, a vertical distance between a lower surface of the green light emitting layer and a lower surface of the second blue light emitting layer may be at least 1.5 times a vertical distance between the reflective electrode and the lower surface of the green light emitting layer.

A vertical distance between a lower surface of the red light emitting layer and a lower surface of the first blue light emitting layer may be at least two times a vertical distance between the lower surface of the second blue light emitting layer and the lower surface of the red light emitting layer.

In a light emitting display device according to one embodiment of the present disclosure, among the red light emitting layer, the green light emitting layer, and the first and second blue light emitting layers, the green light emitting layer may be the thickest, and the red light emitting layer may be the thinnest.

In a light emitting display device according to one embodiment of the present disclosure, the transparent electrode may be separately provided in each of the plurality of sub-pixels and is connected to a transistor between the substrate and the light emitting device, and the reflective electrode may be continuously provided over the plurality of sub-pixels.

A light emitting display device according to one embodiment of the present disclosure may comprise a substrate on which a plurality of sub-pixels is disposed and a light emitting device in each of the plurality of sub-pixels, the light emitting device comprising a transparent electrode and a reflective electrode facing each other, and an intermediate layer disposed between the transparent electrode and the reflective electrode, wherein the intermediate layer includes a first common layer, a first light emitting layer, a second common layer, a second light emitting layer, a third common layer, a third light emitting layer, a fourth common layer, a fourth light emitting layer, and a fifth common layer, which are sequentially disposed in a direction from the transparent electrode toward the reflective electrode, and wherein a thickness of at least one of the first to fifth common layers is disposed so that, at least one of the first to fourth light emitting layers is shifted by a predetermined vertical distance toward the transparent electrode from a maximum cavity peak position relative to the reflective electrode.

In a light emitting display device according to one embodiment of the present disclosure, the first light emitting layer may be a red light emitting layer, the second light emitting layer may be a first blue light emitting layer, the third light emitting layer may be a green light emitting layer, and the fourth light emitting layer may be a second blue light emitting layer.

In a light emitting display device according to one embodiment of the present disclosure, a thickness of the third common layer may be disposed so that, the red light emitting layer and the first blue light emitting layer are shifted toward the transparent electrode, and the green light emitting layer and the second blue light emitting layer may be located at the maximum cavity peak position.

In a light emitting display device according to one embodiment of the present disclosure, a thickness of the fifth common layer may be disposed so that, the second blue light emitting layer are shifted toward the transparent electrode, and a vertical distance from the reflective electrode to a lower surface of the second blue light emitting layer may be greater than 53 nm.

In a light emitting display device according to one embodiment of the present disclosure, a thickness of the intermediate layer may be 482 nm or more.

In a light emitting display device according to one embodiment of the present disclosure, the first light emitting layer may be a green light emitting layer, the second light emitting layer may be a first blue light emitting layer, the third light emitting layer may be a red light emitting layer, and the fourth light emitting layer may be a second blue light emitting layer; the first light emitting layer may be a first blue light emitting layer, the second light emitting layer may be a green light emitting layer, the third light emitting layer may be a second blue light emitting layer, and the fourth light emitting layer may be a red light emitting layer; the first light emitting layer may be a first blue light emitting layer, the second light emitting layer may be a green light emitting layer, the third light emitting layer may be a red light emitting layer, and the fourth light emitting layer may be a second blue light emitting layer; or the first light emitting layer may be a first blue light emitting layer, the second light emitting layer may be a red light emitting layer, the third light emitting layer may be a second blue light emitting layer, and the fourth light emitting layer may be a green light emitting layer.

It will be apparent to those skilled in the art that various modifications and variations can be made in the light emitting display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A light emitting display device, comprising:
a substrate on which a plurality of sub-pixels is disposed; and
a light emitting device in each of the plurality of sub-pixels, the light emitting device comprising a transparent electrode and a reflective electrode facing each other, and a first light emitting stack comprising a first light emitting layer, a first charge generation layer on the first light emitting stack, a second light emitting stack comprising a second light emitting layer on the first charge generation layer, a second charge generation layer on the second light emitting stack, a third light emitting stack comprising a third light emitting layer on the second charge generation layer, a third charge generation layer on the third light emitting stack, and a fourth light emitting stack comprising a fourth light emitting layer on the third charge generation layer, between the transparent electrode and the reflective electrode,
wherein at least one of the first to fourth light emitting layers is shifted by a predetermined vertical distance toward the transparent electrode from a maximum cavity peak position relative to the reflective electrode.

2. The light emitting display device according to claim 1, wherein the vertical distance is equal to or greater than 30 Å and equal to or less than 140 Å.

3. The light emitting display device according to claim 1, wherein: the first to fourth light emitting stacks comprise common layers disposed on and under the first to fourth light emitting layers, and
the vertical distance is located within the common layers.

4. The light emitting display device according to claim 1, wherein the maximum cavity peak position of the fourth light emitting layer, closest to the reflective electrode, is located at a first vertical distance from the reflective electrode, the first vertical distance being 0.115 times a wavelength of light emitted from the fourth light emitting layer,
the maximum cavity peak position of the third light emitting layer is located at a second vertical distance from the reflective electrode, the second vertical distance being a sum of the first vertical distance and a value obtained by dividing a wavelength of light emitted from the third light emitting layer by 2n, n being a refractive index of an intermediate layer between the transparent electrode and the reflective electrode,
the maximum cavity peak position of the second light emitting layer is located at a third vertical distance from the reflective electrode, the third vertical distance being a sum of the second vertical distance and a value obtained by dividing a wavelength of light emitted from the second light emitting layer by 2n, and
the maximum cavity peak position of the first light emitting layer is located at a fourth vertical distance from the reflective electrode, the fourth vertical distance being a sum of the third vertical distance and a value obtained by dividing a wavelength of light emitted from the first light emitting layer by 2n.

5. The light emitting display device according to claim 4, wherein the fourth light emitting layer is spaced apart from the reflective electrode by a vertical distance greater than the first vertical distance by at least 30 Å,
the third light emitting layer is spaced apart from the reflective electrode by a vertical distance greater than the second vertical distance by at least 30 Å,
the second light emitting layer is spaced apart from the reflective electrode by a vertical distance greater than the third vertical distance by at least 30 Å, or
the first light emitting layer is spaced apart from the reflective electrode by a vertical distance greater than the fourth vertical distance by at least 30 Å.

6. The light emitting display device according to claim 1, wherein the first to fourth light emitting layers comprise a red light emitting layer, a green light emitting layer, and first and second blue light emitting layers.

7. The light emitting display device according to claim 6, wherein the first to fourth light emitting layers are disposed between the transparent electrode and the reflective electrode in an order of the red light emitting layer, the first blue light emitting layer, the green light emitting layer, and the second blue light emitting layer.

8. The light emitting display device according to claim 7, wherein a vertical distance between a lower surface of the second blue light emitting layer and a lower surface of the green light emitting layer is at least three times a vertical distance between the reflective electrode and the lower surface of the second blue light emitting layer.

9. The light emitting display device according to claim 7, wherein a vertical distance between a lower surface of the first blue light emitting layer and a lower surface of the red light emitting layer is at least two times a vertical distance between a lower surface of the green light emitting layer and the lower surface of the first blue light emitting layer.

10. The light emitting display device according to claim 6, wherein the first to fourth light emitting layers are disposed between the transparent electrode and the reflective electrode in an order of the green light emitting layer, the first blue light emitting layer, the red light emitting layer, and the second blue light emitting layer.

11. The light emitting display device according to claim 10, wherein a vertical distance between a lower surface of the second blue light emitting layer and a lower surface of the red light emitting layer is at least 3.8 times a vertical distance between the reflective electrode and the lower surface of the second blue light emitting layer, and
a vertical distance between a lower surface of the first blue light emitting layer and a lower surface of the green light emitting layer is at least 1.8 times a vertical distance between the lower surface of the red light emitting layer and the lower surface of the first blue light emitting layer.

12. The light emitting display device according to claim 6, wherein the first to fourth light emitting layers are disposed between the transparent electrode and the reflective electrode in an order of the first blue light emitting layer, the green light emitting layer, the second blue light emitting layer, and the red light emitting layer.

13. The light emitting display device according to claim 12, wherein a vertical distance between a lower surface of the red light emitting layer and a lower surface of the second blue light emitting layer is at least 1.25 times a vertical distance between the reflective electrode and the lower surface of the red light emitting layer, and
a vertical distance between a lower surface of the green light emitting layer and a lower surface of the first blue light emitting layer is at least 0.3 times a vertical distance between the lower surface of the second blue light emitting layer and the lower surface of the green light emitting layer.

14. The light emitting display device according to claim 6, wherein the first to fourth light emitting layers are disposed between the transparent electrode and the reflective electrode in an order of the first blue light emitting layer, the green light emitting layer, the red light emitting layer, and the second blue light emitting layer.

15. The light emitting display device according to claim 14, wherein a vertical distance between a lower surface of the second blue light emitting layer and a lower surface of the red light emitting layer is at least 3.8 times a vertical distance between the reflective electrode and a lower surface of the second blue light emitting layer, and
a vertical distance between a lower surface of the green light emitting layer and the lower surface of the first blue light emitting layer is at least 0.55 times a vertical distance between the lower surface of the red light emitting layer and the lower surface of the green light emitting layer.

16. The light emitting display device according to claim 6, wherein the first to fourth light emitting layers are disposed between the transparent electrode and the reflective electrode in an order of the first blue light emitting layer, the red light emitting layer, the second blue light emitting layer, and the green light emitting layer.

17. The light emitting display device according to claim 16, wherein a vertical distance between a lower surface of the green light emitting layer and a lower surface of the second blue light emitting layer is at least 1.5 times a vertical distance between the reflective electrode and the lower surface of the green light emitting layer, and
a vertical distance between a lower surface of the red light emitting layer and a lower surface of the first blue light emitting layer is at least two times a vertical distance between the lower surface of the second blue light emitting layer and the lower surface of the red light emitting layer.

18. The light emitting display device according to claim 6, wherein, among the red light emitting layer, the green light emitting layer, and the first and second blue light emitting layers, the green light emitting layer is the thickest, and the red light emitting layer is the thinnest.

19. The light emitting display device according to claim 1, wherein the transparent electrode is separately provided in each of the plurality of sub-pixels and is connected to a transistor between the substrate and the light emitting device, and
the reflective electrode is continuously provided over the plurality of sub-pixels.

20. A light emitting display device, comprising:
a substrate on which a plurality of sub-pixels is disposed; and
a light emitting device in each of the plurality of sub-pixels, the light emitting device comprising a transparent electrode and a reflective electrode facing each other, and an intermediate layer disposed between the transparent electrode and the reflective electrode,
wherein the intermediate layer includes a first common layer, a first light emitting layer, a second common layer, a second light emitting layer, a third common layer, a third light emitting layer, a fourth common layer, a fourth light emitting layer, and a fifth common layer, which are sequentially disposed in a direction from the transparent electrode toward the reflective electrode, and
wherein a thickness of at least one of the first to fifth common layers is disposed so that, at least one of the first to fourth light emitting layers is shifted by a predetermined vertical distance toward the transparent electrode from a maximum cavity peak position relative to the reflective electrode.
